(19) United States
(12) Patent Application Publication
(10) Pub. No.: US 2007/0096602 A1
(43) Pub. Date: May 3, 2007

(54) Impact drive actuator and lens drive device using the same

(75) Inventor: Kaoru Matsuki, Kawasaki-shi (JP)

Correspondence Address: Scully, Scott, Murphy & Presser, 400 Garden City Plaza, Garden City, NY, 11530-3319, US

(73) Assignee: Olympus Corporation, Tokyo (JP)

(21) Appl. No.: 11/591,109

(22) Filed: Nov. 1, 2006

(30) Foreign Application Priority Data
Nov. 2, 2005 (JP) 2005-319867

(51) Int. Cl. H01L 41/00

(52) U.S. Cl. 310/338; 310/311

(57) ABSTRACT

An impact drive actuator comprises a vibrator fixed to a fixing member and configured to generate slight displacement in a first direction and a second direction, a vibration member configured to reciprocate by the slight displacement of the vibrator, a motion object set on the vibration member, an adsorption power control part configured to control adsorption power between the motion object and the vibration member, and a guide member having an end fixed to the fixing member, and provided along the vibration member. The motion object is supported clamped between the vibration member and the guide member so as to be engaged with each of the vibration member and the guide member. The adsorption power controlled by the adsorption power control part creates a difference between frictional force between the motion object and the vibration member and frictional force between the motion object and the guide member.

### CROSS-REFERENCE TO RELATED APPLICATIONS

This application is based upon and claims the benefit of priority from prior Japanese Patent Application No. 2005-319867, filed Nov. 2, 2005, the entire contents of which are incorporated herein by reference.

### BACKGROUND OF THE INVENTION

1. Field of the Invention

The present invention relates to an impact drive actuator which drives a motion object, and to a lens drive device using the same.

2. Description of the Related Art

There is a known actuator in which an electromechanical transducer element linked to a drive shaft is supplied with drive pulses of a saw-tooth waveform to displace the drive shaft in an axial direction so that a movable member frictionally engaged with the drive shaft is moved in the axial direction. This kind of actuator will be hereinafter called an impact drive actuator.

This kind of impact drive actuator is disclosed in, for example, U.S. Pat. No. 5,589,723. Driving of the impact drive actuator is achieved by applying to a piezoelectric element a drive pulse having a waveform consisting of a gently rising part and a successive steep falling part. That is, the gently rising part of the drive pulse causes the piezoelectric element to extend gently in thickness directions, so that a drive shaft linked to the piezoelectric element is displaced in an axial direction (which is the first direction). Therefore, a motion object frictionally engaged with the drive shaft is moved in the same direction as the axial direction. The steep falling part of the drive pulse causes the piezoelectric element to contract rapidly in thickness directions, so that the drive shaft is displaced in another axial direction (which is the second direction opposite to the first direction). At this time, the motion object frictionally engaged with the drive shaft is not moved but stays substantially at the present position due to inertial force which overcomes frictional engagement force between the object and the drive shaft. In this case, use of the term “substantially” means including even a movement as follows. That is, the motion object moves following the drive shaft in both the first and second directions while causing a slippage between the object and the shaft, and the motion object moves as a whole in the first direction due to a difference in drive time. Styles of movements are determined under given frictional conditions.

By thus applying sequentially drive pulses having a waveform described above to a piezoelectric element, the motion object can be moved sequentially in the first direction.

On the contrary, movement of the motion object in the opposite direction (the second direction) to the first direction can be achieved by applying to the piezoelectric element drive pulses having a waveform consisting of a steep rising part and a successive gently falling part.

### BRIEF SUMMARY OF THE INVENTION

According to a first aspect of the present invention, there is provided an impact drive actuator comprising:

a fixing member;

a vibrator fixed to the fixing member and configured to generate slight displacement in a first direction and a second direction opposite to the first direction;

a vibration substrate having a first flat face and configured to reciprocate by the slight displacement of the vibrator;

a motion object set on the first flat face of the vibration substrate and having a second flat face in a plane opposed to the first flat face;

an adsorption power control part configured to control adsorption power between the motion object and the vibration substrate; and

a motion object hold part having an end fixed to the fixing member, and provided along the vibration substrate, wherein

the motion object is supported clamped between the vibration substrate and the motion object hold part so as to be engaged with each of the vibration substrate and the motion object hold part, and

the adsorption power controlled by the adsorption power control part creates a difference between frictional force between the motion object and the vibration substrate and frictional force between the motion object and the motion object hold part.

According to a second aspect of the present invention, there is provided a lens drive device comprising:

an impact drive actuator including:
a fixing member;
a vibrator fixed to the fixing member and configured to generate slight displacement in a first direction and a second direction opposite to the first direction;
a vibration substrate having a first flat face and configured to reciprocate by the slight displacement of the vibrator;
a motion object set on the first flat face of the vibration substrate and having a second flat face in a plane opposed to the first flat face;
an adsorption power control part configured to control adsorption power between the motion object and the vibration substrate; and
a motion object hold part having an end fixed to the fixing member, and provided along the vibration substrate, wherein
the motion object is supported clamped between the vibration substrate and the motion object hold part so as to be engaged with each of the vibration substrate and the motion object hold part, and
the adsorption power controlled by the adsorption power control part creates a difference between frictional force between the motion object and the vibration substrate and frictional force between the motion object and the motion object hold part; and

an optical element provided on the motion object of the impact drive actuator.

According to a third aspect of the present invention, there is provided a lens drive device comprising:

an impact drive actuator including:
a fixing member;
a vibrator fixed to the fixing member and configured to generate slight displacement in a first direction and a second direction opposite to the first direction;
a vibration substrate having a first flat face and configured to reciprocate by the slight displacement of the vibrator;
a motion object set on the first flat face of the vibration substrate and having a second flat face in a plane opposed to the first flat face;
an adsorption power control part configured to control adsorption power between the motion object and the vibration substrate; and
a motion object hold part having an end fixed to the fixing member, and provided along the vibration substrate, wherein
the motion object is supported clamped between the vibration substrate and the motion object hold part so as to be engaged with each of the vibration substrate and the motion object hold part, and
the adsorption power controlled by the adsorption power control part creates a difference between frictional force between the motion object and the vibration substrate and frictional force between the motion object and the motion object hold part;

plural fixed lenses provided at the motion object hold part of the impact drive actuator, the motion object hold part having a function as a lens barrel; and

one of an optical element set on the motion object of the impact drive actuator and an optical element linked to the motion object by a link member formed on the motion object of the impact drive actuator, the optical element provided to be movable along an axial direction of the lens barrel inside the lens barrel.

According to a fourth aspect of the present invention, there is provided an impact drive actuator comprising:

a fixing member;

a vibrator fixed to the fixing member and configured to generate slight displacement in a first direction and a second direction opposite to the first direction;

a vibration substrate having a first flat face and configured to reciprocate by the slight displacement of the vibrator;

a motion object set on the first flat face of the vibration substrate and having a second flat face in a plane opposed to the first flat face;

a first electrode provided on the first flat face;

a second electrode provided on the motion object, opposed to the first electrode;

a guide member having an end fixed to the fixing member, and provided along the vibration substrate, the motion object is supported clamped between the vibration substrate and the guide member so as to be engaged with each of the vibration substrate and the guide member; and

a controller configured to control adsorption power between the motion object and the vibration substrate by applying a potential difference between the first and second electrodes, the adsorption power being generated by the first and second electrodes and causing a difference between frictional force between the motion object and the vibration substrate and frictional force between the motion object and the guide member.

According to a fifth aspect of the present invention, there is provided an impact drive actuator comprising:

a fixing member;

displacement generation means fixed to the fixing member and for generating slight displacement in a first direction and a second direction opposite to the first direction;

a vibration substrate having a first flat face and for reciprocating by the slight displacement of the displacement generation means;

a motion object set on the first flat face of the vibration substrate and having a second flat face in a plane opposed to the first flat face;

adsorption power controlling means for controlling adsorption power between the motion object and the vibration substrate; and

motion object holding means having an end fixed to the fixing member, and provided along the vibration substrate, wherein

the motion object is supported clamped between the vibration substrate and the motion object holding means so as to be engaged with each of the vibration substrate and the motion object holding means, and

the adsorption power controlled by the adsorption power controlling means creates a difference between frictional force between the motion object and the vibration substrate and frictional force between the motion object and the motion object holding means.

Advantages of the invention will be set forth in the description which follows, and in part will be obvious from the description, or may be learned by practice of the invention. Advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1A is a perspective view of an impact drive actuator according to a first embodiment of the present invention;

FIG. 1B is an cross-sectional view of the impact drive actuator according to the first embodiment;

FIG. 1C is a side view of the impact drive actuator according to the first embodiment;

FIG. 2 is a view for explaining traces of motion of a motion object;

FIG. 3 is a cross-sectional view of an engagement part between the motion object and a vibration member;

FIG. 4 is a cross-sectional view of an engagement part between a motion object and a vibration member according to a modification of the first embodiment;

FIG. 5 is a cross-sectional view of an engagement part between a motion object and a vibration member according to another modification of the first embodiment;

FIG. 6 is a cross-sectional view of an engagement part between a motion object and a guide member;

FIG. 7A is a perspective view of a lens drive device using an impact drive actuator according to a second embodiment of the present invention;

FIG. 7B is a plan view of a lens drive device according to the second embodiment;

FIG. 7C is a cross-sectional view observed from a side of the lens drive device according to the second embodiment;

FIG. 8 is a cross-sectional view of an engagement part between a motion object and a vibration member;

FIG. 9 is a cross-sectional view of an engagement part between a motion object and a guide member;

FIG. 10A is a perspective view of a lens drive device using an impact drive actuator according to a third embodiment of the present invention;

FIG. 10B is a cross-sectional view of the lens drive device according to the third embodiment, observed from a side of the device;

FIG. 10C is an A-A cross-sectional view of FIG. 10B;

FIG. 11A is a perspective view of a lens drive device using an impact drive actuator according to a fourth embodiment of the present invention;

FIG. 11B is a cross-sectional view of the lens drive device according to the fourth embodiment, observed from a side of the device;

FIG. 11C is an A-A cross-sectional view of FIG. 11B; and

FIG. 11D is a B-B cross-sectional view of FIG. 11B.

### DETAILED DESCRIPTION OF THE INVENTION

Hereinafter, best modes for carrying out the present invention will be described with reference to the drawings.

[First Embodiment]

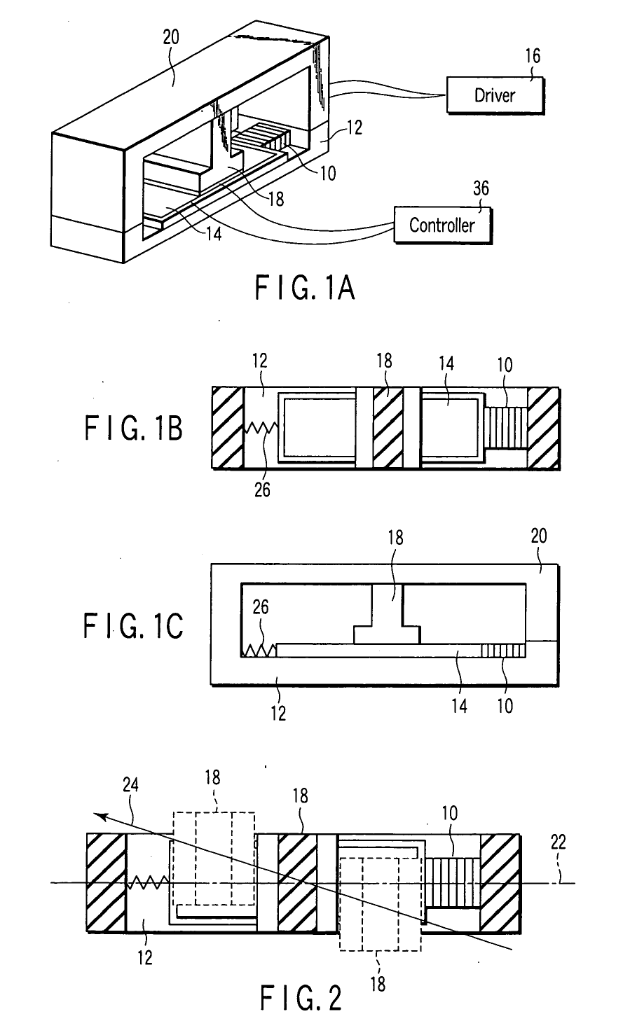

As shown in FIGS. 1A to 1C, in an impact drive actuator according to a first embodiment of the invention, an end of a vibrator 10 as a displacement means constituted by a piezoelectric element is fixed to a fixing member 12. A vibration member 14 as a vibration substrate is attached to another end of the vibrator 10. A voltage supplied to the vibrator 10 from a driver 16 causes the vibrator 10 to be displaced slightly in a first direction and in a second direction opposite to the first direction. This slight displacement causes the vibration member 14 to be displaced slightly in the same directions.

The vibration member 14 has a first flat face on which a motion object 18 is set to be movable in a predetermined direction relative to the fixed member 12. The motion object 18 is supported clamped between the fixing member 12 and a guide member 20 which is a motion object hold means fixed to the fixing member 12 and provided along the vibration member 14. Therefore, not only the motion object 18 and the vibration member 14 are frictionally engaged with each other but also the motion object 18 and the guide member 20 are frictionally engaged with each other. A second flat face of the motion object 18, which is opposite the first flat face of the vibration member 14, and this first flat face of the vibration member 14 contact each other. Therefore, as shown in FIG. 2, the motion object 18 does not stop even if the motion axis 22 of the vibration member 14 and a motion direction 24 of the motion object 18 do not correspond to each other. As a result, the motion object 18 is able to follow traces as indicated by broken lines in the figure. In other words, the motion object 18 is freely movable in the first flat face formed by the vibration member 14.

An opposite side of the vibration member 14 to the side in which the member 14 is attached to the vibrator 10 is pressed toward the vibrator 10 by an elastic member 26 such as a spring.

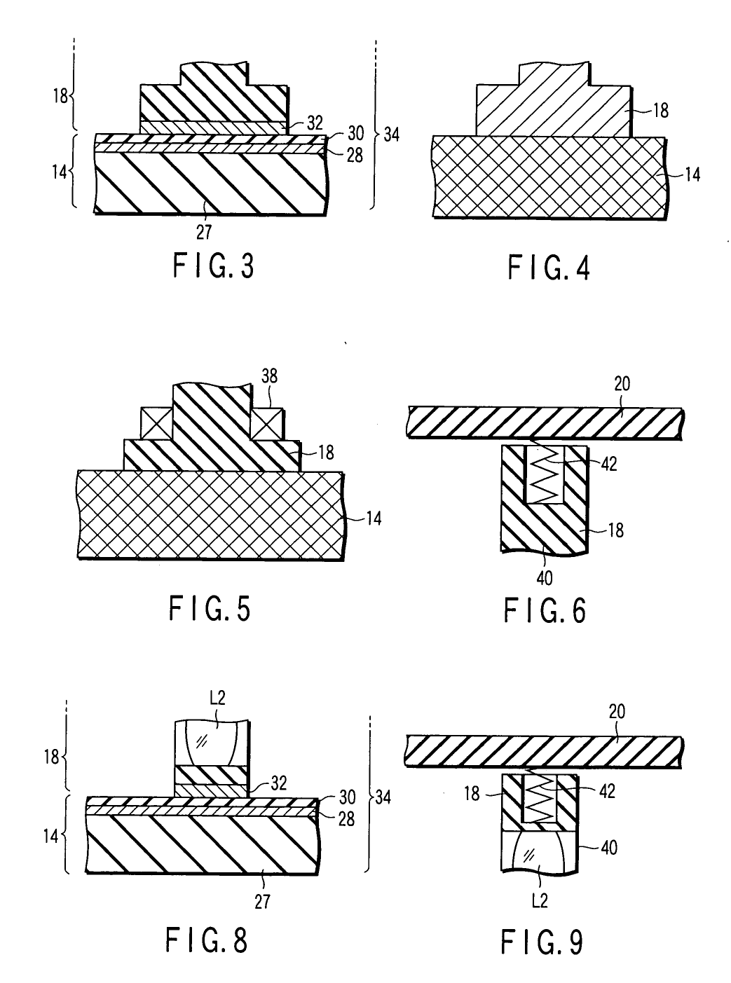

As shown in FIG. 3, the vibration member 14 is formed by layering an electrode 28 (hereinafter called a first electrode) and an insulating material 30 on a substrate 27 forming the first flat face. An electrode 32 (hereinafter called a second electrode) is formed on an opposite face of the motion object 18 to the vibration member 14. The first electrode 28 provided on the vibration member 14, and the second electrode 32 formed on the opposite face (second flat face) thereof to the vibration member 14 are opposed to each other through the insulating material 30. The insulating material 30 may be formed in bottom of the second electrode 32 instead of forming it on the first electrode 28.

This structure constitutes an adsorption power control part 34 which controls adsorption power between the motion object 18 and the vibration member 14. That is, frictional force between the motion object 18 and vibration member 14 can be changed if electrostatic force is generated by making a potential difference between the first electrode 28 and the second electrode 32 from a controller 36. This change in frictional force causes a difference in friction force between the motion object 18 and the vibration member 14 and between the motion object 18 and the guide member 20. Therefore, the motion object 18 is made movable by applying a predetermined waveform to the vibrator 10 by the driver 16. In the structure using electrostatic force as described above, each electrode can be formed thin so that the actuator can be downsized.

Although the adsorption power control part 34 is changed by electrostatic force, the present invention is not limited to this structure. For example, as shown in FIG. 4, the vibration member 14 may be made of a permanent magnet and the motion object 18 may be made of a magnetic material such as iron. This kind of structure need not include an electrode in the vibration member 14 or motion object 18. Further, neither the controller 36 nor a wiring for applying a voltage from the controller 36 to an electrode is required. Accordingly, the structure is simplified.

As shown in FIG. 5, it is quite possible that the vibration member 14 is made of a permanent magnet and an electromagnet using a coil 38 is used for the motion object 18. By thus using an electromagnet for the motion object 18, a great force can be generated such as cannot be generated electrostatically. Accordingly, more stable driving can be achieved.

As described above, the guide member 20 can support the motion object 18 so as to raise a degree of freedom in motion. Further, as shown in FIG. 6, a coil spring 42 as an elastic member may be inserted between an upper face of a vertical part 40 of the motion object 18 and the guide member 20. By adopting this structure, (pressing) force for supporting the motion object 18 can be managed easily so that desired pressing force can be supplied stably to the motion object 18. That is, frictional force between the motion object 18 and the guide member 20 can be managed easily.

Although the coil spring 42 is used in the above case, the structure may be constituted by any member such as a plate spring as long as the member is an elastic member.

[Second Embodiment]

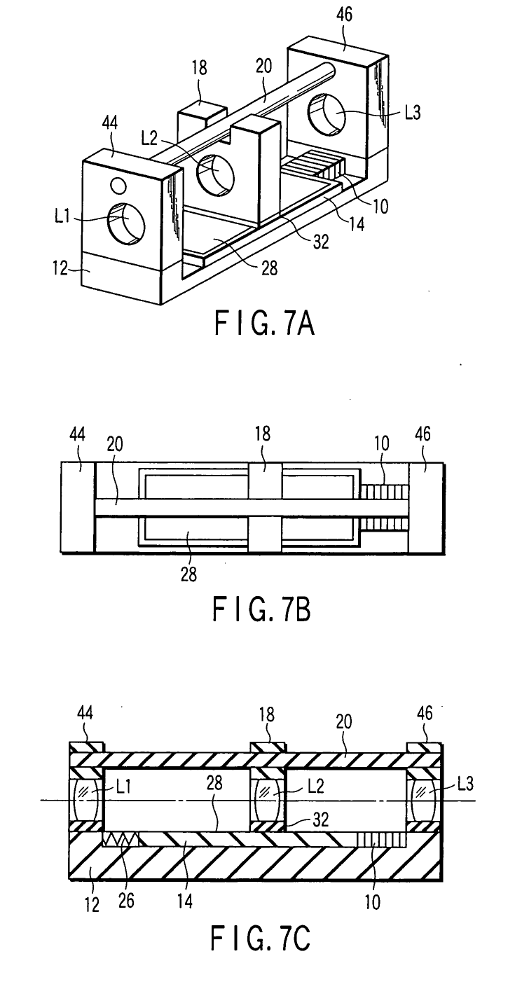

As shown in FIGS. 7A to 7C, a lens drive device using an impact drive actuator according to a second embodiment of the present invention drives a lens L2 among three lenses of L1, L2, and L3.

That is, the basic structure of the impact drive actuator according to this embodiment is the same as that of the first embodiment described above. However, in the lens drive device in the present embodiment, the motion object 18 of such an impact drive actuator serves also as a support frame for supporting the lens L2. In addition, a front lens frame 44 in which a fixed lens L1 is set, and a rear lens frame 46 in which a fixed lens L3 is set are attached to the fixing member 12.

As in the first embodiment, the motion object 18 and the vibration member 14 are frictionally engaged with each other, as well as the motion object 18 and the guide member 20 are frictionally engaged with each other, in the lens drive device according to the present embodiment. Therefore, if the guide member 20 is a guide shaft, the motion object 18 and the vibration member 14 contact each other on faces of their own, so that the motion object 18 is movable in a face of the vibration member 14. Accordingly, the motion object 18 can be moved stably and accurately along the guide shaft.

As shown in FIGS. 8 and 9, if the impact drive actuator is used in a lens drive device, a coil spring 42 is inserted between the motion object 18 and the guide member 20, as in the first embodiment described above. Thus, stable pressing is achieved, and accuracy of movement based on frictional engagement with the guide shaft is guaranteed.

To make the lens drive mechanism as compact as possible, the adsorption power control part 34 is constructed as a simple structure as shown in FIG. 8 which causes electrostatic force to act. Of course, it is quite possible to use a mechanism in which electromagnetic force is caused to act using an electromagnet and a permanent magnet without using electrostatic force, as described in the first embodiment.

[Third Embodiment]

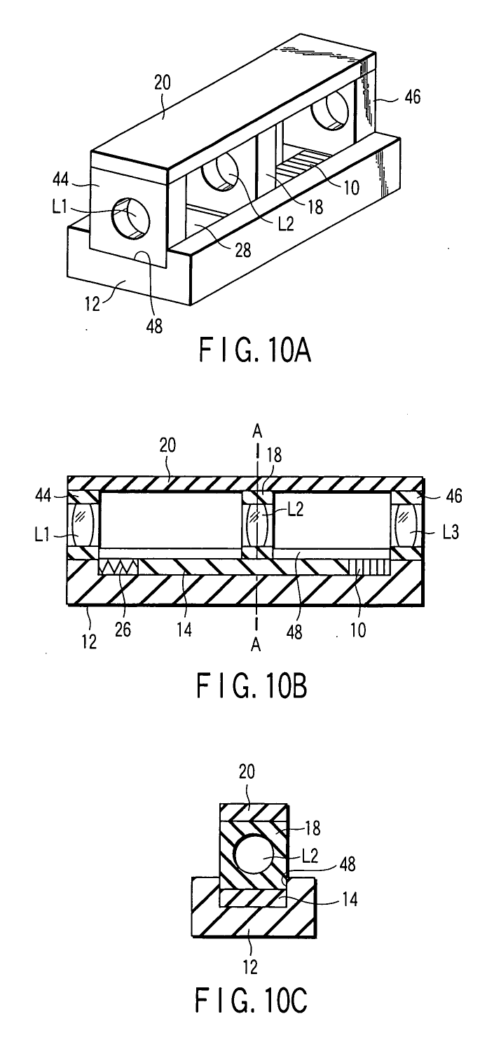

As shown in FIGS. 10A to 10C, a lens drive device using an impact drive actuator according to a third embodiment of the present invention drives a lens L2 among three lenses of L1, L2, and L3, as in the second embodiment described above.

In the lens drive device according to this embodiment, a guide groove 48 for guiding the motion object 18 is provided in the fixing member 12. That is, the fixing member 12 is constructed so as to serve also as a guide shaft for a lens.

By thus providing the guide groove 48 in the fixing member 12, the vibration member 14 is displaced along the guide groove 48. Therefore, motion of the motion object is more stable and guarantees high operation accuracy.

[Fourth Embodiment]

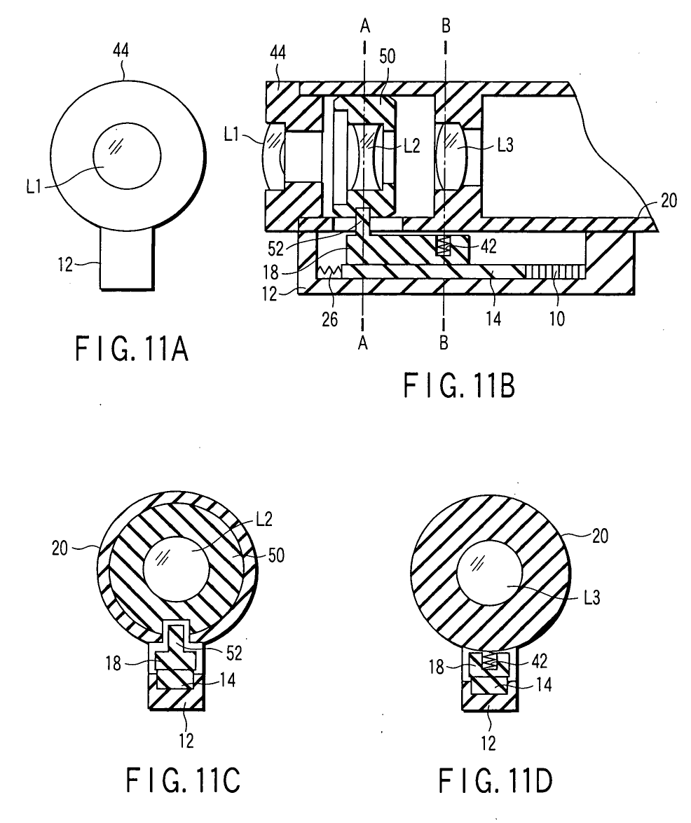

As shown in FIGS. 11A to 11D, a lens drive device using an impact drive actuator according to a fourth embodiment of the present invention drives a lens L2 among three lenses of L1, L2, and L3, like in the second embodiment described above.

In the lens drive device according to this embodiment, the guide member 20 serves also as a lens barrel which fixes fixed lenses L1 and L3. In this lens barrel, a lens hold member 50 including a lens L2 provided to be freely movable in axial directions thereof is linked to the motion object 18 with a predetermined clearance maintained therebetween by a link member 52 formed on the motion object 18.

In this case, the motion object 18 is frictionally engaged with the lens barrel having an optical axis, and the motion object 18 and the vibration member 14 contact each other on flat faces of their own, as in the third embodiment described above. Thus, the degree of freedom in motion of the motion object 18 is raised.

Accordingly, if the lens is arranged to have an optical axis corresponding to the optical axis of the lens barrel, the lens can be moved coaxially to the optical axis of the lens barrel without moving the actuator along the optical axis as long as the lens hold member 50 can be moved by the link member 52.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. An impact drive actuator comprising:
a fixing member;
a vibrator fixed to the fixing member and configured to generate slight displacement in a first direction and a second direction opposite to the first direction;
a vibration substrate having a first flat face and configured to reciprocate by the slight displacement of the vibrator;
a motion object set on the first flat face of the vibration substrate and having a second flat face in a plane opposed to the first flat face;
an adsorption power control part configured to control adsorption power between the motion object and the vibration substrate; and
a motion object hold part having an end fixed to the fixing member, and provided along the vibration substrate, wherein
the motion object is supported clamped between the vibration substrate and the motion object hold part so as to be engaged with each of the vibration substrate and the motion object hold part, and
the adsorption power controlled by the adsorption power control part creates a difference between frictional force between the motion object and the vibration substrate and frictional force between the motion object and the motion object hold part.

2. The actuator according to claim 1, wherein the adsorption power control part includes:
a first electrode formed on the first flat face of the vibration substrate; and
a second electrode formed on the second flat face of the motion object and opposed to the first electrode through an insulating layer, to control electrostatic adsorption power by a potential difference between the first and second electrodes.

3. The actuator according to claim 1, wherein the adsorption power control part includes:
a permanent magnet set on the vibration substrate; and
an electromagnet set on the motion object, opposed to the permanent magnet, to control electromagnetic adsorption power between the permanent magnet and the electromagnet by a current applied to the electromagnet.

4. The actuator according to claim 1, wherein the adsorption power control section includes:
a permanent magnet set on the vibration substrate; and
a magnetic material set opposed to the permanent magnet.

5. The actuator according to claim 1, further comprising an elastic member inserted between the motion object and the motion object hold part.

6. A lens drive device comprising:
an impact drive actuator including:
a fixing member;
a vibrator fixed to the fixing member and configured to generate slight displacement in a first direction and a second direction opposite to the first direction;
a vibration substrate having a first flat face and configured to reciprocate by the slight displacement of the vibrator;
a motion object set on the first flat face of the vibration substrate and having a second flat face in a plane opposed to the first flat face;
an adsorption power control part configured to control adsorption power between the motion object and the vibration substrate; and
a motion object hold part having an end fixed to the fixing member, and provided along the vibration substrate, wherein
the motion object is supported clamped between the vibration substrate and the motion object hold part so as to be engaged with each of the vibration substrate and the motion object hold part, and
the adsorption power controlled by the adsorption power control part creates a difference between frictional force between the motion object and the vibration substrate and frictional force between the motion object and the motion object hold part; and
an optical element provided on the motion object of the impact drive actuator.

7. The device according to claim 6, further comprising a fixed lens set on the fixing member of the impact drive actuator.

8. The device according to claim 7, wherein the motion object hold part of the impact drive actuator serves also as a guide corresponding to an optical axis of the optical element and to an optical axis of the fixed lens.

9. The device according to claim 7, wherein the fixing member of the impact drive actuator serves also as a guide corresponding to an optical axis of the optical element and to an optical axis of the fixed lens.

10. A lens drive device comprising:
an impact drive actuator including:
a fixing member;
a vibrator fixed to the fixing member and configured to generate slight displacement in a first direction and a second direction opposite to the first direction;
a vibration substrate having a first flat face and configured to reciprocate by the slight displacement of the vibrator;
a motion object set on the first flat face of the vibration substrate and having a second flat face in a plane opposed to the first flat face;
an adsorption power control part configured to control adsorption power between the motion object and the vibration substrate; and
a motion object hold part having an end fixed to the fixing member, and provided along the vibration substrate, wherein
the motion object is supported clamped between the vibration substrate and the motion object hold part so as to be engaged with each of the vibration substrate and the motion object hold part, and
the adsorption power controlled by the adsorption power control part creates a difference between frictional force between the motion object and the vibration substrate and frictional force between the motion object and the motion object hold part;
plural fixed lenses provided at the motion object hold part of the impact drive actuator, the motion object hold part having a function as a lens barrel; and
one of an optical element set on the motion object of the impact drive actuator and an optical element linked to the motion object by a link member formed on the motion object of the impact drive actuator, the optical element provided to be movable along an axial direction of the lens barrel inside the lens barrel.

11. An impact drive actuator comprising:
a fixing member;
a vibrator fixed to the fixing member and configured to generate slight displacement in a first direction and a second direction opposite to the first direction;
a vibration substrate having a first flat face and configured to reciprocate by the slight displacement of the vibrator;
a motion object set on the first flat face of the vibration substrate and having a second flat face in a plane opposed to the first flat face;
a first electrode provided on the first flat face;
a second electrode provided on the motion object, opposed to the first electrode;
a guide member having an end fixed to the fixing member, and provided along the vibration substrate, the motion object is supported clamped between the vibration substrate and the guide member so as to be engaged with each of the vibration substrate and the guide member; and
a controller configured to control adsorption power between the motion object and the vibration substrate by applying a potential difference between the first and second electrodes, the adsorption power being generated by the first and second electrodes and causing a difference between frictional force between the motion object and the vibration substrate and frictional force between the motion object and the guide member.

12. An impact drive actuator comprising:
a fixing member;
displacement generation means fixed to the fixing member and for generating slight displacement in a first direction and a second direction opposite to the first direction;
a vibration substrate having a first flat face and for reciprocating by the slight displacement of the displacement generation means;
a motion object set on the first flat face of the vibration substrate and having a second flat face in a plane opposed to the first flat face;
adsorption power controlling means for controlling adsorption power between the motion object and the vibration substrate; and
motion object holding means having an end fixed to the fixing member, and provided along the vibration substrate, wherein
the motion object is supported clamped between the vibration substrate and the motion object holding means so as to be engaged with each of the vibration substrate and the motion object holding means, and
the adsorption power controlled by the adsorption power controlling means creates a difference between frictional force between the motion object and the vibration substrate and frictional force between the motion object and the motion object holding means.
